(19) United States
(12) Patent Application Publication
(10) Pub. No.: US 2026/0259253 A1
(43) Pub. Date: Sep. 3, 2026

(54) Synchronization of Distribution System Sensor Data Using Phasor Measurement Units

(71) Applicant: Quanta Technology, LLC, Raleigh, NC (US)

(72) Inventors: David G. Hart, Raleigh, NC (US); Zheyuan Cheng, Apex, NC (US); Aditya Joshi, Raleigh, NC (US); Srinivas Varadan, Cary, NC (US); Richard Carpenter, Fuquay Varina, NC (US)

(21) Appl. No.: 19/555,302

(22) Filed: Mar. 3, 2026

Related U.S. Application Data
(60) Provisional application No. 63/765,872, filed on Mar. 3, 2025.

(51) Int. Cl. G01R 29/18; G01R 21/133

(52) U.S. Cl. CPC G01R 29/18; G01R 21/133

(57) ABSTRACT

Computer equipment receives a phasor measurement unit (PMU) data stream captured by one or more PMUs in a power distribution system, the PMU data stream being time-synchronized to a global time source. The computer equipment receives a sensor data stream captured by a distribution sensor in the power distribution system, the sensor data stream not being time-synchronized to the global time source. The computer equipment applies dynamic time warping (DTW) processing to the sensor data stream and the PMU data stream to calculate a warping path that minimizes a DTW distance between signal shapes in the sensor data stream and corresponding signal shapes in the PMU data stream. The computer equipment performs monitoring, control, and/or event analysis using the warping path and/or the sensor data stream as warped in time according to the warping path to be time-aligned with the PMU data stream.

### RELATED APPLICATIONS

The present application claims priority to U.S. Provisional Patent Application Ser. No. 63/765,872, filed Mar. 3, 2025 and entitled “Synchronization of Distribution System Sensor Data Using Phasor Measurement Units”, the entire contents of which is incorporated by reference herein.

### TECHNICAL FIELD

The present application relates generally to a power distribution system, and relates more particularly to synchronization of sensor data streams in such a system.

### BACKGROUND

In modern power distribution systems, operational decisions and analytics increasingly rely on combining data from multiple data sources deployed across the system, including, for example, data from supervisory control and data acquisition (SCADA), power quality meters (PQM), relays, reclosers, and smart meters in an advanced metering infrastructure (AMI) system. Each of these data sources can provide useful insights into power system operation and performance. However, the different data sources are often deployed, operated, and engineered separately, and may therefore use different timekeeping mechanisms, reporting cadences, and/or data formats.

By way of example, the different data sources may report data at different time resolutions and in different forms. SCADA typically reports status information and measurements such as voltage magnitude and current magnitude at a distribution substation or feeder recloser every 3-5 seconds. Relays may collect information by exception, such as voltage and current waveforms and breaker status following a fault. PQMs may similarly collect voltage and current waveforms by exception following events such as voltage sags or swells. Smart meters may collect interval data such as voltage magnitude, current magnitude, power factor, watt hours, or var hours over time intervals measured in minutes; for large commercial or industrial customers the intervals may be 1 to 60 minutes, and for residential customers the intervals may be 15 to 60 minutes.

As a result, data sources in a power distribution system may exhibit timing inconsistencies due to clock offsets, sampling-rate differences, reporting-period differences, communication latency, device configuration, and/or other factors. Such timing inconsistencies can misrepresent power system operation or performance by, for example, causing events to appear out of order, yielding inaccurate event start times or durations, and/or producing incorrect correlations of cause and effect across data sources. This in turn can degrade the accuracy and reliability of operational decisions and analytics that depend on combining the different data sources.

### SUMMARY

Some embodiments herein apply dynamic time warping (DTW) processing to leverage a phasor measurement unit (PMU) data stream as a time reference for other distribute sensor data stream(s) in a power distribution system. Some embodiments for example apply DTW processing to time-align sensor data stream(s) to the PMU data stream, e.g., by minimizing DTW distance between corresponding signal shapes in the streams. By exploiting DTW in this way, some embodiments advantageously reduce timing inconsistencies among heterogeneous data sources, for realizing improved accuracy and reliability of operational decisions and analytics in the power distribution system.

More particularly, embodiments herein include a method performed by computer equipment. The method comprises receiving a phasor measurement unit (PMU) data stream captured by one or more PMUs in a power distribution system, the PMU data stream being time-synchronized to a global time source. The method also comprises receiving a sensor data stream captured by a distribution sensor in the power distribution system, the sensor data stream not being time-synchronized to the global time source. The method also comprises applying dynamic time warping (DTW) processing to the sensor data stream and the PMU data stream to calculate a warping path that minimizes a DTW distance between signal shapes in the sensor data stream and corresponding signal shapes in the PMU data stream. The method also comprises performing monitoring, control, and/or event analysis in the power distribution system using the warping path and/or the sensor data stream as warped in time according to the warping path to be time-aligned with the PMU data stream.

Other embodiments herein include a non-transitory computer-readable storage medium on which is stored instructions that, when executed by processing circuitry of computer equipment, causes the computer equipment to receive a phasor measurement unit (PMU) data stream captured by one or more PMUs in a power distribution system, the PMU data stream being time-synchronized to a global time source. The non-transitory computer-readable storage medium also causes the computer equipment to receive a sensor data stream captured by a distribution sensor in the power distribution system, the sensor data stream not being time-synchronized to the global time source. The non-transitory computer-readable storage medium also causes the computer equipment to apply dynamic time warping (DTW) processing to the sensor data stream and the PMU data stream to calculate a warping path that minimizes a DTW distance between signal shapes in the sensor data stream and corresponding signal shapes in the PMU data stream. The non-transitory computer-readable storage medium also causes the computer equipment to perform monitoring, control, and/or event analysis in the power distribution system using the warping path and/or the sensor data stream as warped in time according to the warping path to be time-aligned with the PMU data stream.

Other embodiments herein include computer equipment comprising processing circuitry configured to receive a phasor measurement unit (PMU) data stream captured by one or more PMUs in a power distribution system, the PMU data stream being time-synchronized to a global time source. The processing circuitry is also configured to receive a sensor data stream captured by a distribution sensor in the power distribution system, the sensor data stream not being time-synchronized to the global time source. The processing circuitry is also configured to apply dynamic time warping (DTW) processing to the sensor data stream and the PMU data stream to calculate a warping path that minimizes a DTW distance between signal shapes in the sensor data stream and corresponding signal shapes in the PMU data stream. The processing circuitry is also configured to perform monitoring, control, and/or event analysis in the power distribution system using the warping path and/or the sensor data stream as warped in time according to the warping path to be time-aligned with the PMU data stream.

Of course, the present disclosure is not limited to the above features and advantages. Indeed, those skilled in the art will recognize additional features and advantages upon reading the following detailed description, and upon viewing the accompanying drawings.

### BRIEF DESCRIPTION OF THE DRAWINGS

FIG. 1 is a block diagram of distribution sensor arrangements and data sources in a simplified distribution system according to some embodiments.

FIG. 2 is a block diagram for applying dynamic time warping processing according to some embodiments.

FIG. 3 presents a logic flow diagram for DTW processing according to some embodiments.

FIG. 4 presents exemplary graphs of warping a sensor data stream to match a phasor measurement unit (PMU) data stream according to some embodiments.

FIG. 5 presents an exemplary graph of an aligned time series after dynamic time warping, according to some embodiments.

FIG. 6 presents exemplary voltage outage scenarios according to some embodiments.

FIG. 7 is a logic flow diagram of a method performed by a computer equipment in accordance with particular embodiments.

FIG. 8 illustrates a computing equipment as implemented in accordance with one or more embodiments.

### DETAILED DESCRIPTION

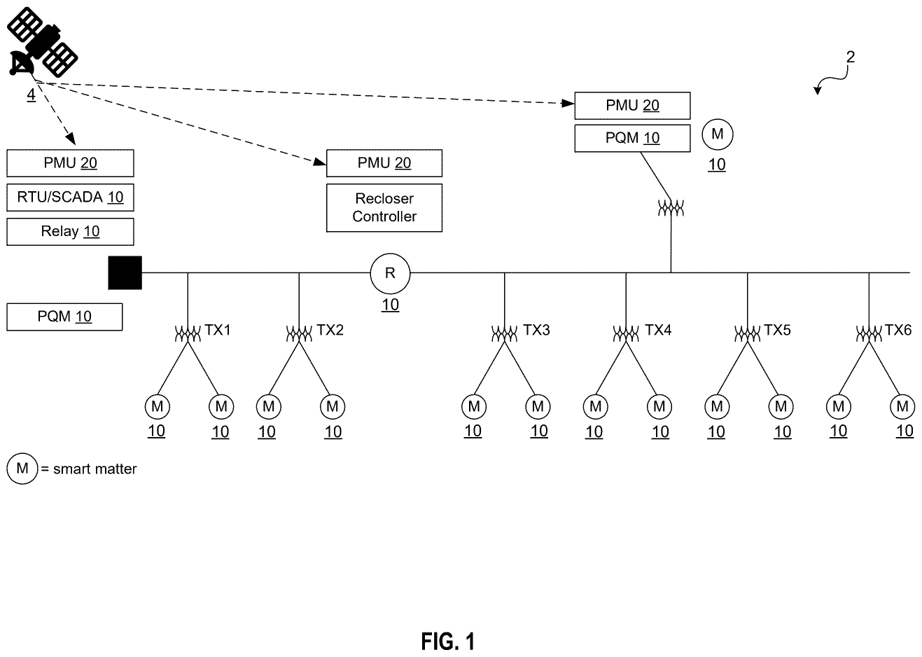

FIG. 1 presents a diagram showing a power distribution system 2 according to some embodiments, e.g., in simplified form for purposes of explanation. In general, the power distribution system 2 includes distribution infrastructure configured to deliver electric power from one or more upstream sources to downstream loads through distribution equipment such as one or more substations, distribution feeders, switches, reclosers, and/or other protective or control devices. The power distribution system 2 may further include one or more distributed energy resources and/or interconnection points, and/or one or more customer sites, any of which may include monitoring, protection, and/or metering equipment. Although shown in simplified form, the power distribution system 2 may include additional components, devices, and configurations (e.g., radial and/or networked feeder topologies, sectionalizing devices, capacitor banks, voltage regulators, and the like).

In this context, the power distribution system 2 includes one or more distribution sensors 10. The distribution sensor(s) 10 may function as sources of sensed data, e.g., captured from different locations in the power distribution system 2. Different distribution sensor(s) 10 may produce streams of sensor data having different sampling rates, reporting cadences, data formats, and/or timing characteristics. By way of example shown in FIG. 1, the distribution sensor(s) 10 may include one or more supervisory control and data acquisition (SCADA) devices that report status and/or analog measurements (e.g., voltage magnitude and current magnitude), e.g., at a substation and/or along a feeder at periodic intervals (e.g., every few seconds). In some embodiments, the distribution sensor(s) 10 alternatively or additionally include protective devices such as relays and/or reclosers that capture information by exception, such as voltage and current waveforms and breaker/recloser status following a fault or switching operation. In other embodiments, the distribution sensor(s) 10 may include one or more power quality meters (PQM) that capture waveform data and/or power quality event information by exception (e.g., in response to voltage sag, swell, or interruption conditions). In still other embodiments, the distribution sensor(s) 10 may alternatively or additionally include one or more smart meters of an advanced metering infrastructure (AMI) system that capture interval measurements such as voltage magnitude, current magnitude, power factor, watt hours, and/or var hours, and/or that record event-related information such as outage or restoration indications.

The power distribution system 2 also includes one or more phasor measurement units (PMUs) 20. The PMU(s) 20 are configured to provide phasor measurements that are time-synchronized to a global time source 4, such as global positioning satellites (GPS) or an equivalent timing reference. The measurements may for instance include voltage and/or current phasors (e.g., magnitude and angle). In some embodiments, the PMU(s) 20 each provide a measurement stream at a comparatively high reporting rate, e.g., reporting phasor measurements at a rate corresponding to one or more power system cycles.

As illustrated in FIG. 1, distribution sensor(s) 10 and/or PMU(s) 20 may be installed at various locations in the power distribution system 2 depending on the deployment scenario. For example, PMU(s) 20 may be deployed at a substation, at a feeder recloser or other feeder device, at a major customer site, and/or at a renewable energy interconnection point. In some embodiments, distribution sensor(s) 10 in the form of PQM(s) may be installed at the substation, at a major customer site, and/or at a renewable energy interconnection point to capture power quality events and/or waveform records at those locations. In some embodiments, distribution sensor(s) 10 in the form of smart meters may be installed at one or more customer sites and/or at a renewable energy interconnection point, for example to capture interval consumption and/or voltage information and/or to provide outage and restoration indications for those sites.

In some embodiments, the distribution sensor(s) 10 and the PMU(s) 20 provide data to one or more computing and/or analytics components (not shown in FIG. 1) via one or more communication networks. Such communication networks may include utility communication infrastructure, wireless networks, carrier networks, and/or other links suitable for transporting operational and measurement data. In some embodiments, the data may be stored, processed, and/or analyzed locally (e.g., at a substation or feeder device), centrally at a utility data center, and/or in a cloud computing environment.

The data produced by the distribution sensor(s) 10 and the PMU(s) 20 may be provided as one or more data streams, where each data stream comprises an ordered sequence of data samples or records associated with respective time instants or time intervals. In some embodiments, a data stream is continuous or near-continuous (e.g., the PMU data stream providing periodic phasor measurements at a relatively high reporting rate), while other data streams are periodic at lower rates (e.g., SCADA measurements every few seconds or smart meter interval measurements over minutes) and/or event-driven (e.g., relay/recloser oscillographic waveform captures or PQM waveform captures generated by exception when a triggering condition occurs). Accordingly, different data streams may differ in sampling rate, sample timing regularity, latency, record duration, and/or representation (e.g., phasor values, magnitudes, interval energy values, waveform samples, and/or status indications), and may include gaps, missing values, or zero values in certain operating conditions such as outages.

In some embodiments, a PMU data stream is time-synchronized to a global time reference 4 in the sense that each PMU measurement is associated with a time indication that is disciplined to a common absolute time source (e.g., a GPS-derived time base), such that PMU measurements captured at different locations are comparable on an absolute time axis. In practical terms, global time synchronization for a PMU data stream may mean that the PMU's internal clock is maintained in alignment with the global time reference 4 and that the PMU reports phasor measurements with time indications that correspond to defined instants relative to that global time reference 4. As a result, the PMU data stream can serve as a high-confidence timing reference for distribution events, including event start times, event progression, and/or event end times, and can be used to correlate measurements across geographically separated PMU installations.

By contrast, one or more other distribution sensor data streams may not be synchronized to the same global time reference 4. Such streams may rely on local device clocks, local control clocks, or centrally distributed time that may be subject to offset, drift, update delay, communication latency, and/or configuration differences. For example, a smart meter may receive time updates through an AMI head-end mechanism that can introduce time errors across meters; a relay, recloser, or PQM may record event data using a local clock that is not GPS-disciplined; and SCADA time indications may reflect polling and transport delays rather than the physical time of the measured condition. Accordingly, even when these other data streams include time indications, those time indications may not be consistent across devices or comparable to the PMU's global-time axis without additional processing, and the timing differences can cause misalignment of corresponding events or signal shapes/features between the PMU data stream and the other sensor data streams. Generally, then, while the PMU(s) 20 may provide globally time-synchronized data, one or more of the distribution sensor(s) 10 may not be time-synchronized to the same global time source 4 and may exhibit clock offsets, drift, communication latency, and/or other timing inconsistencies.

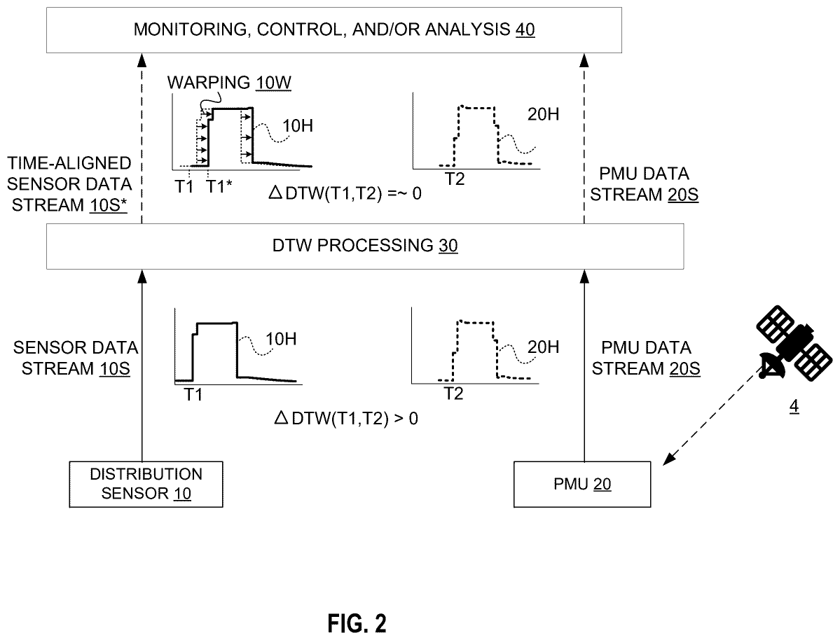

FIG. 2 illustrates some embodiments for leveraging a globally synchronized PMU data stream as a time reference for other distribution sensor data stream(s). In the example of FIG. 2, a sensor data stream 10S is obtained from one or more distribution sensors 10 in the power distribution system 2, and a PMU data stream 20S is obtained from one or more PMUs 20. As described above, the PMU data stream 20S is time-synchronized to a global time source 4 and therefore provides a reliable time reference. The sensor data stream 10S may not be time synchronized to the global time source 4 and may include one or more timing inconsistencies, such as clock offset, drift, reporting latency, irregular sampling, and/or other timing differences relative to the PMU data stream 20S.

In some embodiments, dynamic time warping (DTW) processing 30 is applied to the sensor data stream 10S and the PMU data stream 20S to determine a correspondence between the streams based on similarity of their temporal patterns. This DTW processing 30 refers to a procedure that compares two temporal sequences and determines a mapping between samples of the sequences that reduces mismatch between the sequences when one sequence is allowed to be “warped” along the time axis. DTW processing 30 may be applied to any suitable representation of the sensor data stream 10S and the PMU data stream 20S, including phasor quantities, magnitudes, interval quantities, waveform-derived features, and/or other measurement values, depending on the data source and the analysis objective. For example, in embodiments where the sensor data stream 10S is received in a time-domain representation (e.g., waveform samples), the time-domain representation may first be converted to a phasor-representation of the sensor data stream 10S to provide a representation that is comparable to the PMU data stream 20S. DTW processing 30 is then applied to the phasor-representation of the sensor data stream 10S and the PMU data stream 20S. Moreover, in some embodiments, DTW processing 30 is applied to selected portions of the streams (e.g., event portions), and in other embodiments DTW processing 30 is applied to broader time intervals, for example to establish a time correspondence over a longer monitoring period.

In some embodiments, DTW processing 30 produces a warping path 10W. The warping path 10W refers to an ordered set of correspondences between indices (or samples) in the sensor data stream 10S and indices (or samples) in the PMU data stream 20S. The warping path 10W may also be referred to as an alignment path, alignment mapping, time correspondence mapping, or match path. The warping path 10W may be monotonic in the sense that it preserves temporal order (i.e., later samples in one stream are not mapped to earlier samples in the other stream), while still permitting non-uniform stretching and compression so that a particular temporal shape/feature in the sensor data stream 10S can be matched to the corresponding temporal shape/feature in the PMU data stream 20S even when the two streams have different sampling rates, different reporting cadences, different timing offsets, or otherwise different timing characteristics. In some embodiments, the warping path 10W represents many-to-one or one-to-many correspondences, such as where multiple samples from one stream correspond to a single sample (or shorter sequence) of the other stream, e.g., due to differences in resolution or sampling.

In some embodiments, the warping path 10W permits non-uniform time stretching and compression while maintaining monotonic time order. The non-uniform nature of the time stretching and compression means that different portions of the sensor data stream 10S may be effectively expanded or contracted in time by different amounts, rather than being shifted by a single constant offset. This can occur, for example, where portions of a sensor stream progress more slowly or more quickly than the corresponding portions of the PMU stream due to differing reporting cadences, buffering and transport delays, clock drift, or device-specific filtering and triggering behavior. Maintenance of monotonic time order means that the correspondence defined by the warping path 10W preserves the forward progression of time, i.e., later samples (or later portions) of the sensor data stream 10S map to later samples (or later portions) of the PMU data stream 20S, so that the alignment does not reorder time or map a later portion of an event to an earlier portion. In this way, the warping path 10W can accommodate local timing differences while still producing a physically meaningful alignment of an event's onset, progression, and recovery.

This use of DTW differs from applications such as speech recognition in which warping is often constrained to reflect linguistic structure (e.g., phoneme or state sequences) and corresponding duration constraints. In speech recognition, strict warping constraints prevent alignments that would be inconsistent with plausible pronunciations, such as skipping or repeating linguistic units in ways that violate expected phonetic order or duration. In contrast, in the present distribution sensing context, the objective is to align temporal structure of measured electrical phenomena, i.e., to match corresponding signal shapes produced by the same physical event across heterogeneous sensors, rather than to enforce alignment with a predefined linguistic-state topology. Accordingly, some embodiments focus the DTW processing 30 on capturing shape similarity and timing correspondence of power-system events (e.g., faults, sags/swells, switching operations, outage/restoration transitions) under monotonic time order, while permitting the warping path 10W to flexibly stretch and compress time as needed to accommodate differences in sampling rate, reporting cadence, and/or timing error between the PMU data stream 20S and the sensor data stream 10S.

In some embodiments, DTW processing 30 calculates the warping path 10W by minimizing a DTW distance ΔDTW between the streams. Such a DTW distance ΔDTW may refer to an aggregate distance measure that evaluates mismatch between the streams under a candidate warping path. In some embodiments, the DTW distance ΔDTW is computed from a pointwise distance metric (e.g., Euclidean distance) applied to paired samples identified by the warping path 10W, and the aggregate DTW distance ΔDTW reflects the cumulative mismatch across the aligned samples. DTW processing 30 seeks a warping path 10W that minimizes the DTW distance ΔDTW, thereby identifying a correspondence between the streams that aligns similar temporal behavior while tolerating timing differences. In some embodiments, DTW processing 30 may incorporate one or more constraints consistent with the DTW framework, such as maintaining monotonic time order and continuity of the mapping, while permitting non-uniform temporal stretching and compression to achieve robust matching.

In some embodiments, DTW processing 30 operates on “signal shapes” 10H and 20H of the respective streams. A signal shape in this regard refers to a characteristic temporal pattern, signature, or trajectory of one or more measured quantities in a data stream. For example, a signal shape may include the onset, magnitude, and recovery profile of a voltage sag, the temporal profile of a fault current rise and decay, a switching transient signature, a restoration profile following an outage, or other time-varying behavior that is observable in one or more measured quantities. Signal shapes may be represented as sequences of values over time and may include, depending on the data source, phasor magnitudes and/or angles, voltage or current magnitudes, power factor, real or reactive power, energy interval values, waveform-derived phasors, and/or combinations thereof. In some embodiments, the same physical event in the power distribution system 2 produces corresponding signal shapes in both the sensor data stream 10S and the PMU data stream 20S, but those shapes may be temporally offset or temporally distorted due to the timing inconsistencies described above. DTW processing 30 leverages the similarity of these shapes to determine the warping path 10W.

In some embodiments, applying the DTW processing 30 involves computing, e.g., by dynamic programming, a DTW distance matrix of cumulative distances between samples of the sensor data stream 10S and samples of the PMU data stream 20S. In these embodiments, each entry of the DTW distance matrix corresponds to a pairing between a sensor-data sample at index i and a PMU-data sample at index j, and a cumulative distance for the index pair (i, j) is computed as (i) a local dissimilarity measure, such as a Euclidean distance between the sensor-data sample at index i and the PMU-data sample at index j, plus (ii) a minimum of cumulative distances previously computed for predecessor index pairs (i−1, j), (i, j−1), and (i−1, j−1). In this case, dynamic programming recurrence evaluates, at each index pair, the least-cost way to reach that pair under allowable DTW transitions, thereby building an aggregate DTW distance that reflects mismatch across an entire alignment. In some embodiments, the warping path 10W is then determined based on the DTW distance matrix, e.g., by tracing back through the predecessor relationships from a terminal index pair to an initial index pair to recover the sequence of index-pair correspondences that achieves the minimized DTW distance. The resulting warping path 10W thus represents the computed time correspondence between the sensor data stream 10S and the PMU data stream 20S.

In some embodiments, the warping path 10W is used to perform time-alignment of the sensor data stream 10S relative to the PMU data stream 20S, yielding a warped sensor data stream 10S* that is substantially time-aligned with the PMU data stream 20S. Time-alignment here refers to adjusting the effective time placement of samples of the sensor data stream 10S so that temporal shapes/features in the sensor data stream 10S correspond to the same physical time instants (or corresponding time instants) as temporal shapes/features in the PMU data stream 20S. In some embodiments, time-aligning the sensor data stream 10S with the PMU data stream 20S comprises aligning the sensor data stream 10S and the PMU data stream 20S on a common timescale referenced to the global time source 4 by warping the sensor data stream 10S in time according to the warping path 10W such that samples of the sensor data stream 10S correspond to samples of the PMU data stream 20S at common time points. Time-alignment may be achieved by warping the sensor data stream 10S in time according to the warping path 10W, e.g., by shifting, stretching, compressing, and/or resampling the sensor data stream 10S to form the warped sensor data stream 10S*.

In some embodiments, this time-alignment is selectively performed for certain portions of the sensor data stream 10S (e.g., event portions that capture identified or targeted events). For example, event data in the sensor data stream 10S that represents an event in the power distribution system 2 (such as a fault, switching operation, voltage sag or swell, breaker operation, restoration, or other disturbance) may be correlated with corresponding event data in the PMU data stream 20S that represents the corresponding event. In such embodiments, DTW processing 30 is applied to the event data in the sensor data stream 10S and the corresponding event data in the PMU data stream 20S, rather than to an entire long-duration record, to calculate a warping path 10W that minimizes a DTW distance ΔDTW between signal shapes 10H represented by the event data in the sensor data stream 10S and corresponding signal shapes 20H represented by the corresponding event data in the PMU data stream 20S. This event-focused correlation and DTW processing can reduce ambiguity when multiple events occur within a long PMU data stream, reduce computational burden, and/or improve robustness by concentrating the alignment on the salient temporal signature of the event, while still allowing the resulting warping path 10W to warp the event portion.

In some embodiments, though, such time-alignment may be omitted altogether, in favor of just using the warping path 10W directly, as described further below. In these embodiments, the warping path 10W itself is treated as an alignment artifact that encodes the time correspondence between the sensor data stream 10S and the PMU data stream 20S without necessarily modifying, resampling, or rewriting the sensor data stream 10S into a warped stream 10S*. For example, the warping path 10W may be used to associate samples, intervals, or event segments from the sensor data stream 10S with corresponding samples or segments in the PMU data stream 20S on the global-time axis, thereby enabling comparisons and analytics “through” the warping path itself rather than by transforming the underlying data. Thus, even where explicit time-alignment of the sensor data stream 10S is not performed, the warping path 10W can still provide the core temporal linkage needed to improve monitoring, control, and/or event analysis across heterogeneous distribution data sources.

In this regard, FIG. 2 shows that monitoring, control, and/or event analysis 40 may be performed in the power distribution system 2 using the warping path 10W and/or using the warped sensor data stream 10S* that is time-aligned with the PMU data stream 20S. Such monitoring may include assessing operating conditions, detecting or confirming events, tracking system performance metrics, or generating situational awareness from combined data sources. Control may include generating or supporting operational actions based on the combined data, such as switching decisions, protection coordination support, voltage regulation actions, or other operational responses, including actions informed by improved time correlation of measurements. Event analysis may include determining event occurrence times, event durations, event sequencing, event classification (e.g., sag versus swell versus interruption), and/or correlating cause-and-effect across devices (e.g., correlating breaker status, relay/recloser operations, and measured electrical quantities). In some embodiments, the warping path 10W itself provides a quantitative representation of timing differences (e.g., time shift and/or drift) between the sensor data stream 10S and the PMU data stream 20S and may be used to validate or correct event timing, to determine synchronization error of a sensor clock (including an AMI system clock), and/or to improve analytics that depend on accurate temporal correlation between heterogeneous data sources.

More particularly, monitoring, control, and/or event analysis 40 may include determining, based on the warping path 10W, a synchronization error of the distribution sensor 10. In these embodiments, the warping path 10W may provide an explicit correspondence between samples (or segments) of the sensor data stream 10S and samples (or segments) of the PMU data stream 20S, and the relative displacement implied by that correspondence can be interpreted as a measure of timing error between the sensor's time base and the global time reference used by the PMU(s) 20. For example, the warping path 10W can be analyzed to determine a relative time shift between the sensor data stream 10S and the PMU data stream 20S at one or more points in time, and/or to determine a time-varying offset indicative of clock drift or accumulated time error. In some embodiments, the synchronization error is determined for a particular event window (e.g., the onset of a fault, sag, switching operation, outage, or restoration), and the synchronization error is expressed as a difference between a sensor-indicated time for the event and a corresponding PMU-indicated time for the event. In some embodiments, synchronization error determination supports detection of timing faults in an AMI time distribution mechanism, non-GPS-synchronized reclosers or PQ meters, or other devices whose timestamps may not reflect global time. The synchronization error may then be used to validate event ordering, correct or normalize event timestamps, or improve analytics that depend on consistent timing across multiple heterogeneous data sources.

In other embodiments, the sensor data stream 10S may comprise an event record captured by the distribution sensor 10 for an event in the power distribution system 2. Such an event record may include, for example, an oscillographic waveform capture, a PQ event capture, breaker/recloser status transitions, sequence-of-events information, a smart meter outage/restoration indication, or other exception-based data associated with a discrete occurrence. In these embodiments, monitoring, control, and/or event analysis 40 may include calculating, validating, and/or classifying an occurrence, timing, and/or duration of the event using the PMU data stream 20S and the time-aligned sensor data stream 10S*. For example, after time-alignment, the aligned streams can be used to determine whether a sensor-reported event occurrence corresponds to a PMU-observed event, to validate or refine an event start time (e.g., fault inception, sag onset, breaker opening) and an event end time (e.g., voltage recovery, breaker closing, restoration), and/or to compute an event duration consistently across devices. In some embodiments, classification is performed by comparing event signatures or temporal shapes in the aligned data, such as distinguishing a sag from an interruption, distinguishing a temporary outage from a sustained outage, or distinguishing a fault event from a switching transient, based on characteristics observed in the PMU data stream 20S and the time-aligned sensor record 10S*. In some embodiments, the aligned streams are also used to correlate cause-and-effect across devices, such as correlating relay/recloser operations, breaker status changes, and measured electrical quantities, thereby improving interpretability and reliability of event analysis and operational response decisions.

In some embodiments, the processing in FIG. 2 may be performed repeatedly for multiple sensor data streams 10S from different distribution sensors 10, thereby aligning or correlating multiple heterogeneous data sources to the globally synchronized PMU data stream 20S. Alternatively or additionally, DTW processing 30 and/or event correlation may be applied within selected time windows, for example to isolate individual events within a long PMU record and to align discrete event-driven captures from relays, reclosers, and/or PQMs to the corresponding event in the PMU data stream 20S. In some embodiments, different representations of the sensor data stream 10S may be used for DTW processing 30 depending on the data source, such as converting time-domain waveform samples to a phasor-representation prior to DTW processing, while still applying the resulting warping path 10W to the original sensor data stream 10S for time-alignment and/or analytics.

In some embodiments, applying the DTW processing 30 comprises applying the DTW processing 30 to a non-outage part of the PMU data stream 20S and a corresponding non-outage part of the sensor data stream 10S. A non-outage part here refers to a portion of a data stream in which the measured quantity or quantities are present and informative for matching signal shapes (e.g., values are not saturated to zero and are not missing as NaN), such that DTW distance minimization can meaningfully align temporal patterns. In contrast, during an outage or blackout condition, many streams may report constant zeros, flat-lined values, or missing values, which may cause DTW processing to become ambiguous or non-informative because different candidate alignments can yield similarly low (or similarly uninformative) distances. Accordingly, some embodiments identify and exclude outage portions from DTW processing 30 and instead apply DTW processing 30 on pre-outage and/or post-outage portions where signal shapes remain suitable for robust matching.

In some embodiments, for an outage part of the sensor data stream 10S that includes zero values or missing values indicative of an outage or blackout, non-DTW processing time-aligns the sensor data stream 10S with the PMU data stream 20S by aligning an outage start time and an outage end time indicated in the sensor data stream 10S with an outage start time and an outage end time detected in the PMU data stream 20S. For example, the sensor data stream 10S may indicate outage timing through explicit timestamps (e.g., a smart meter outage time stamp and restoration time stamp), through a reported outage interval, and/or through a transition of measured values to a sustained zero or missing state. The PMU data stream 20S, as a globally synchronized reference, may detect outage start and end times based on changes in phasor magnitude, disappearance or restoration of voltage, breaker status transitions, and/or other synchronized indications available at the PMU location or associated devices. By aligning these sensor-indicated and PMU-detected outage boundaries, some embodiments establish a reliable time correspondence for the outage portion even where DTW processing is not informative within the outage interval itself.

In some embodiments, then, the combination of DTW processing 30 on non-outage portions and outage-boundary alignment on outage portions provides a hybrid synchronization approach that remains robust across normal operation and outage conditions. In some embodiments, the non-outage DTW-derived warping path 10W is used to align and/or analyze pre-outage and post-outage behavior (e.g., fault inception, sag onset, restoration dynamics), while the outage start/end alignment anchors the outage interval on the PMU's global time reference. This hybrid approach can improve accuracy of outage timing and duration determinations, reduce mis-ordering of events surrounding an outage, and support analytics that combine heterogeneous data streams that may otherwise be difficult to reconcile due to missing or zero-valued measurements during outages.

Embodiments herein accordingly provide one or more methodologies to synchronize various distribution sensor data. Some embodiments in this regard exploit the DTW algorithm for measuring similarity between two or more temporal sequences, e.g., time series data from distribution sensors, and calculates the optimal match between given sequences. In other words, the DTW algorithm tries to align two or more temporal sequences to achieve best similarity. Heretofore, DTW has been used for speech recognition; embodiments herein advantageously exploit DTW in power system sensor data time synchronization.

Generally, then, some embodiments provide a mechanism to synchronize distribution system sensor data, e.g., using a globally synchronized phasor measurement unit. The synchronized sensor dataset can be used for monitoring, control, and/or event analysis.

Some embodiments herein advantageously leverage synchronized measurements for analytics using data from multiple sources. This may in turn produce one or more of the following advantages:
(1) Reliably align sensor data streams with different resolutions.
(2) Reliably align discrete event driven data with continuous PMU data stream.
(3) Can distinguish events within a long PMU data stream and reliably align discrete event data accordingly
(4) Can align sensor data that are collected from different locations in the distribution system.
(5) Can align sensor data streams that are in different formats

Consider now additional details of some embodiments applicable for normal conditions vs outage conditions.

### Distribution Sensor Data Synchronization During Normal Condition

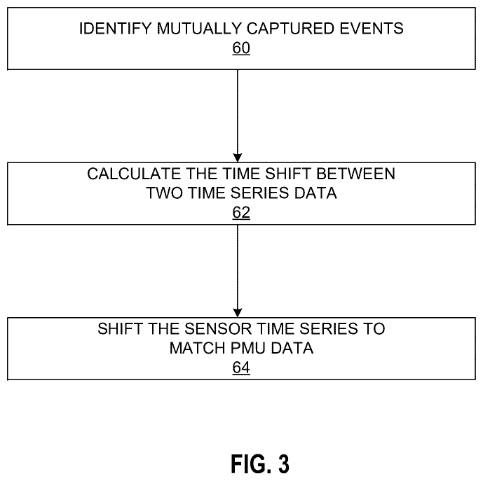

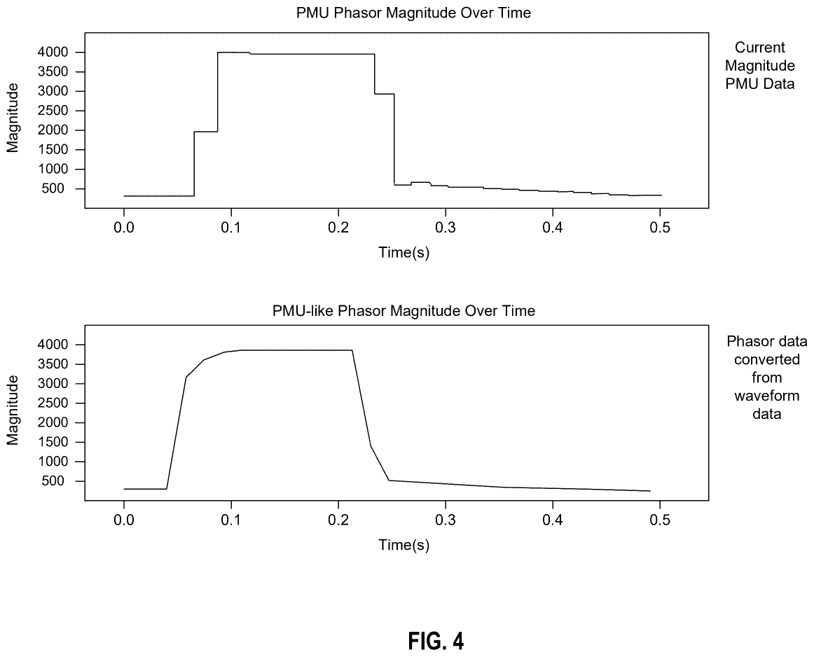

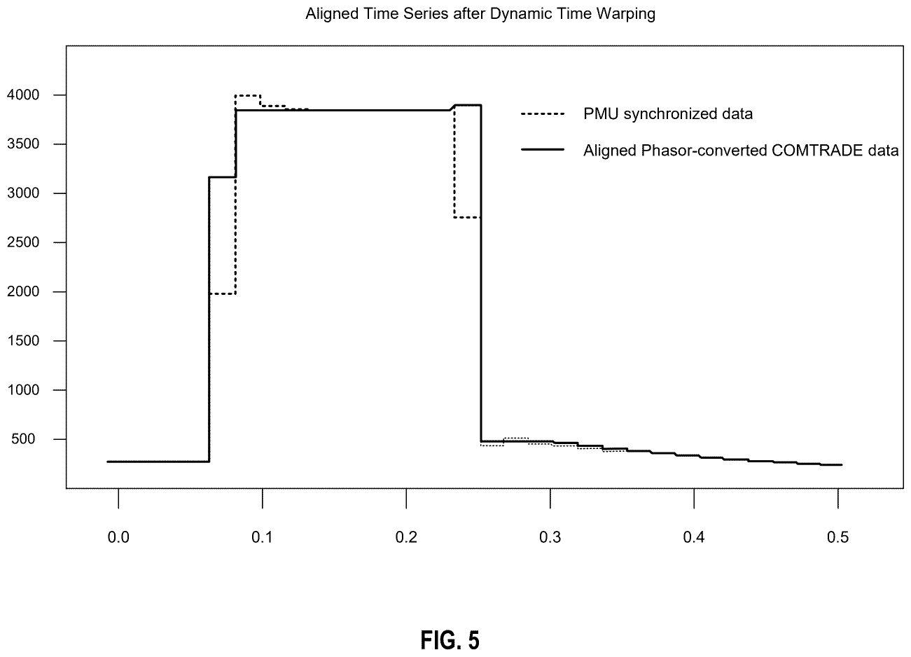

Since a PMU is globally synchronized (e.g., GPS) and provides a continuous data stream, it can be used as a time reference for all other distribution sensor data. FIG. 3 presents an overall flow chart for distribution sensor data synchronization according to some embodiments. The method may align distribution sensor data streams 10S with PMU data streams 20S, e.g., one by one. For two given data streams, e.g., one PMU data stream and one waveform, the method involves capturing one or more data streams, e.g., from a recloser (e.g., in a COMTRADE file format). The method comprises correlating the event captured by the waveform data with a corresponding event captured by PMU data (Block 60). Since PMU data is in phasor format (magnitude and angle) and waveform data is sinusoidal instantaneous data with higher resolution, the method may first involve converting the waveform data into phasor data format, e.g., as shown in FIG. 4 in an example. Then, using the DTW algorithm, the method comprises calculating the time shift between two data streams (Block 62). Once the time difference is calculated, the method involves shifting the original waveform data to match PMU data (Block 64), e.g., as shown in FIG. 5 as an example.

The mathematical details according to some embodiments can be given as follows. Let PMU and COMTRADE data be represented by Xₚ={x_{p,1}, x_{p,2}, x_{p,3} . . . x_{p, N}}, X_{c}={x_{c,1}, x_{c,2}, x_{c,3} . . . x_{p, N}} respectively and dₑ(x_{c,i}, x_{p,j}) be the Euclidean distance between points x_{c,i} and x_{p,j}. The DTW distance to minimize is given by d_{w}(i,j)=dₑ(x_{c,i}, x_{p,j})+min{d(i-1, j), d(i, j−1), d(i−1, j−1)}. In case of applying DTW algorithm for data synchronization in PMU and COMTRADE, one unique aspect of the approach is focusing on minimizing temporal shift or delay by identifying the shape similarity. As compared to DTW in speech recognition, where focus is on linguistic structure with strict warping constraints, in this case it mainly focuses on temporal structure with flexible warping as the sole focus is to capture the similarity and realign the time series. Moreover, even after changing the PMU locations, the DTW algorithm can still be used to capture the shape similarity effectively.

The DTW algorithm in these and other embodiments can reliably align various sensor data accurately even with the presence of multiple events.

### Distribution Sensor Data Synchronization During Outage

In the event of distribution system outage/blackout, the DTW algorithm cannot be applied to align time series data, because all or part of the data sources will report zero value(s) or missing value(s) such as NaN (not a number). In this scenario, some embodiments detect the outage start and end time in PMU data (time reference), and align other distribution data sources using the outage start/end time stamps in the PMU data.

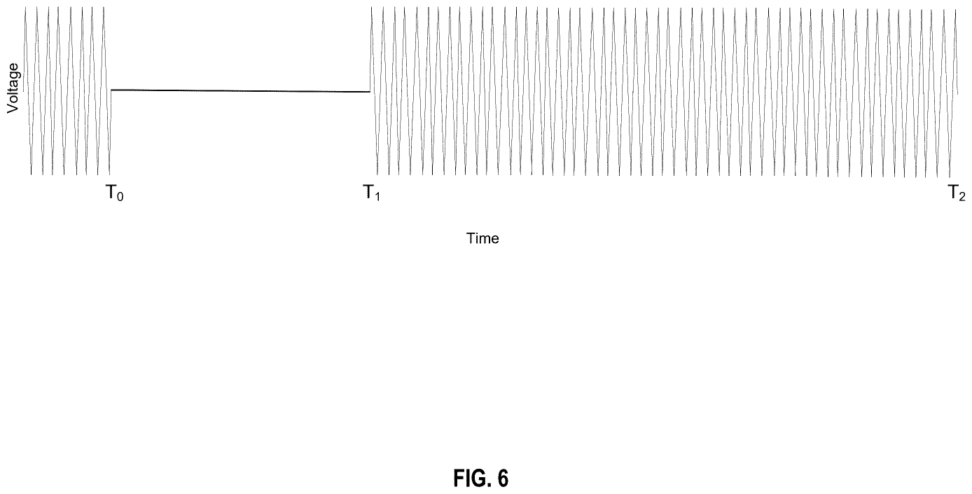

Consider the following voltage outage scenarios as shown in FIG. 6. Utilities analyze the duration, frequency and number of customers impacted by outages. For duration, metrics typically evaluate sustained outages greater than a defined period such as 3 minutes. Outages less than the defined period are temporary outages. In FIG. 6, a sustained outage is where T1-T0 is greater or equal to 3 minutes, while a temporary outage is where T1-T0 is less than 3 minutes. After T2 another outage may not occur, or a temporary outage can occur, or a sustained outage can occur.

Smart meters may be used to alarm an Outage Management System (OMS) when an outage occurs and when voltage is restored. The data in smart meters such as outage time stamp, restoration time stamp, and/or outage interval may be used to determine which customers were impacted by the outage and the extent of the duration on the customer.

### AMI Time Synchronization Error Detection

AMI systems may rely on a central server to maintain time and distribute the time to smart meters across the system. The PMUs rely on a GPS-based signal to maintain very accurate synchronization and report the phasors every 1-2 cycles. GPS time synched measurement(s) can be derived from phasors in a PMU in substation relays or feeder reclosers, or from synchronized measurements from a PQ meter for digital fault recorder (DFR). In a scenario where T1-T0 is greater or equal to 3 minutes, the smart meters will record an outage time and a restoration time. In this case, the outage or restoration time stamp as measured by the synchronized measurements from the PMU, PQ meter, or DFR voltage and breaker status can be used to verify the outage or restoration time stamp measured by the smart meter, align events recorded from various devices with varying time resolution, and/or to calculate a synchronization error of the AMI system. The synchronization error can be used to indicate errors in the AMI system time mechanism or to improve time indication of events.

### Recloser or PQM Time Synchronization Error Detection

In a similar manner, a scenario where a PMU or GPS-based time input is not available at the recloser, customer site, or renewable energy interconnection point, the PMU at the substation can be used to calculate the synchronization error for data in these devices such as waveform capture or outage indication. Thus, the synchronized measurements can be used to align the data from these devices for analytics.

### AMI Outage Time Calculation Error Detection for Sustained Outages

In a scenario where T1-T0 is greater or equal to 3 minutes, the smart meters will record an outage time and a restoration time. In this case, the outage or restoration time stamp as measured by the synchronized measurements voltage and breaker status can be used to determine the outage duration and verify the outage duration measured by the smart meter to calculate a synchronization error of the AMI system. The synchronization error can be used to indicate errors in the AMI system time mechanism and estimate the correct event time.

### AMI Outage Time Calculation Error Detection for Temporary Outages

In a scenario where T1-T0 is less than 3 minutes, the smart meters may not report or record the outage and restoration time stamp of a temporary outage depending on their configuration. AMI meters will not report or record an outage less than a defined value such as 1 minute. The smart meters will continue to record the interval data every 1-60 minutes and indicate outages. In this scenario, the synchronized measurement data can be used to determine the outage duration in conjunction with the smart meter interval data and estimate the correct event time.

### AMI Power Quality Event Detection

In a scenario where an AMI meter detects and records a power quality event, synchronized measurements can be used to validate the detection and duration times. The synchronization error can be used to indicate errors in the AMI system time mechanism and estimate the correct event time.

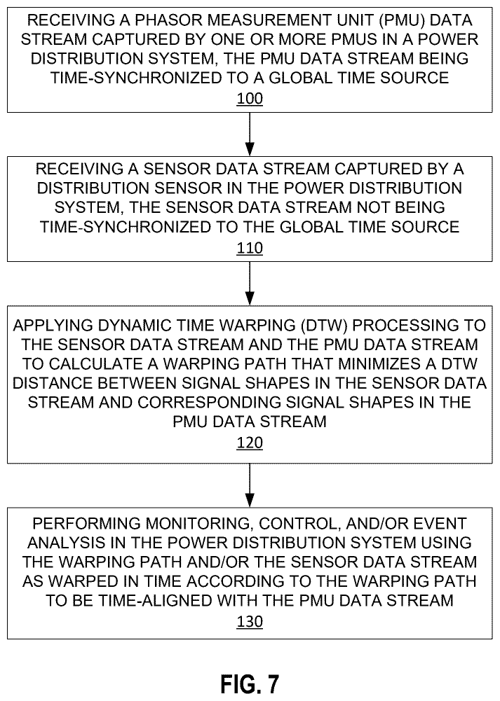

In view of the modifications and variations herein, FIG. 7 depicts a method performed by a computer equipment 100 in accordance with particular embodiments. The method includes receiving a phasor measurement unit (PMU) data stream 20S captured by one or more PMUs 20 in a power distribution system 2, the PMU data stream 20S being time-synchronized to a global time source 4 (Block 100). The method also includes receiving a sensor data stream 10S captured by a distribution sensor 10 in the power distribution system 2, the sensor data stream 10S not being time-synchronized to the global time source 4 (Block 110). The method also includes applying dynamic time warping (DTW) processing 30 to the sensor data stream 10S and the PMU data stream 20S to calculate a warping path 10W that minimizes a DTW distance between signal shapes 10H in the sensor data stream 10S and corresponding signal shapes 20H in the PMU data stream 20S (Block 120). The method also includes performing monitoring, control, and/or event analysis 40 in the power distribution system 2 using the warping path 10W and/or the sensor data stream 10S* as warped in time according to the warping path 10W to be time-aligned with the PMU data stream 20S (Block 130).

In some embodiments, receiving the sensor data stream 10S comprises receiving a time-domain representation of the sensor data stream 10S, and the method further comprises converting the time-domain representation to a phasor-representation of the sensor data stream 10S. In some embodiments, applying the DTW processing 30 comprises applying the DTW processing 30 to the phasor-representation of the sensor data stream 10S and the PMU data stream 20S to calculate the warping path 10W that minimizes the DTW distance between the phasor-representation of the sensor data stream 10S and the PMU data stream 20S.

In some embodiments, the method further comprises correlating event data in the sensor data stream 10S that represents an event in the power distribution system 2 with corresponding event data in the PMU data stream 20S that represents a corresponding event, and applying the DTW processing 30 comprises applying the DTW processing 30 to the event data in the sensor data stream 10S and the corresponding event data in the PMU data stream 20S to calculate a warping path 10W that minimizes a DTW distance between signal shapes 10H represented by the event data in the sensor data stream 10S and corresponding signal shapes 20H represented by the corresponding event data in the PMU data stream 20S. In some embodiments, the event comprises at least one of: a voltage sag, a voltage swell, a fault inception, a breaker open indication, a breaker close indication, a restoration of voltage, a sustained outage, a temporary outage, or a power quality event.

In some embodiments, applying the DTW processing 30 comprises computing, by dynamic programming, a DTW distance matrix of cumulative distances between samples of the sensor data stream 10S and samples of the PMU data stream 20S, wherein a cumulative distance for a pair of sample indices (i, j) is computed as a Euclidean distance between a sensor-data sample at index i and a PMU-data sample at index j plus a minimum of cumulative distances previously computed for index pairs (i-1, j), (i, j−1), and (i−1, j−1) and determining the warping path 10W based on the DTW distance matrix.

In some embodiments, the method further comprises time-aligning the sensor data stream 10S with the PMU data stream 20S by warping the sensor data stream 10S in time according to the warping path 10W, and wherein the monitoring, control, and/or event analysis 40 is performed using the sensor data stream 10S* as warped in time according to the warping path 10W to be time-aligned with the PMU data stream 20S. In some embodiments, time-aligning the sensor data stream 10S with the PMU data stream 20S comprises aligning the sensor data stream 10S and the PMU data stream 20S on a common timescale referenced to the global time source 4 by warping the sensor data stream 10S in time according to the warping path 10W such that samples of the sensor data stream 10S correspond to samples of the PMU data stream 20S at common time points.

In some embodiments, the warping path 10W permits non-uniform time stretching and compression while maintaining monotonic time order

In some embodiments, the PMU data stream 20S and the sensor data stream 10S are captured at different time resolutions and/or at different locations.

In some embodiments, performing monitoring, control, and/or event analysis 40 in the power distribution system 2 comprises determining, based on the warping path 10W, a synchronization error of the distribution sensor 10.

In some embodiments, the sensor data stream 10S comprises an event record captured by the distribution sensor 10 for an event in the power distribution system 2, and performing monitoring, control, and/or event analysis 40 in the power distribution system 2 comprises calculating, validating, and/or classifying an occurrence, timing, and/or duration of the event using the PMU data stream 20S and the time-aligned sensor data stream 10S*.

In some embodiments, the one or more PMUs 20 are installed at a substation, a feeder recloser, a customer site, or a renewable energy interconnection in the power distribution system 2, and the distribution sensor 10 comprises a power quality meter (PQM) installed at the substation, the customer site, or the renewable energy interconnection, or comprises a smart meter installed at a customer site or the renewable energy interconnection.

In some embodiments, the distribution sensor 10 comprises at least one of: a supervisory control and data acquisition (SCADA) device, a power quality meter (PQM), a relay, a recloser, or a smart meter in an advanced metering infrastructure (AMI) system.

In some embodiments, applying the DTW processing 30 comprises applying the DTW processing 30a non-outage part of the PMU data stream 20S and a corresponding non-outage part of the sensor data stream 10S, and the method further comprises, for an outage part of the sensor data stream 10S that includes zero values or missing values indicative of an outage or blackout, time-aligning the sensor data stream 10S with the PMU data stream 20S by aligning an outage start time and an outage end time indicated in the sensor data stream 10S with an outage start time and an outage end time detected in the PMU data stream 20S.

Embodiments herein also include computing equipment 200 configured to perform the method in FIG. 7.

For example, embodiments include computing equipment 200 comprising processing circuitry. The processing circuitry is configured to perform any of the steps of any of the embodiments described above. In some embodiments, the computing equipment 200 further comprises communication circuitry, e.g. for receiving measurement data from one or more data sources.

Embodiments further include computing equipment 200 comprising processing circuitry and memory. The memory contains instructions executable by the processing circuitry whereby the computing equipment 200 is configured to perform any of the steps of any of the embodiments described above.

More particularly, the computing equipment 200 described above may perform the methods herein and any other processing by implementing any functional means, modules, units, or circuitry. In one embodiment, for example, the computing equipment 200 comprise respective circuits or circuitry configured to perform the steps shown in the method figures. The circuits or circuitry in this regard may comprise circuits dedicated to performing certain functional processing and/or one or more microprocessors in conjunction with memory. For instance, the circuitry may include one or more microprocessor or microcontrollers, as well as other digital hardware, which may include digital signal processors (DSPs), special-purpose digital logic, and the like. The processing circuitry may be configured to execute program code stored in memory, which may include one or several types of memory such as read-only memory (ROM), random-access memory, cache memory, flash memory devices, optical storage devices, etc. Program code stored in memory may include program instructions for executing one or more data communications protocols as well as instructions for carrying out one or more of the techniques described herein, in several embodiments. In embodiments that employ memory, the memory stores program code that, when executed by the one or more processors, carries out the techniques described herein.

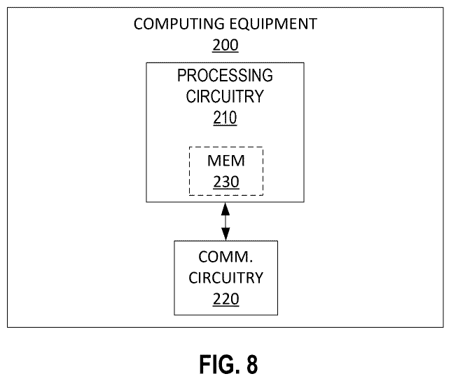

FIG. 8 illustrates computing equipment 200 as implemented in accordance with one or more embodiments. As shown, the computing equipment 200 includes processing circuitry 210 and communication circuitry 220. The communication circuitry 220 is configured to transmit and/or receive information to and/or from one or more other nodes, e.g., via any communication technology, such as one or more sources of measurement data. The processing circuitry 210 is configured to perform processing described above, e.g., in FIG. 7, such as by executing instructions stored in memory 230. The processing circuitry 210 in this regard may implement certain functional means, units, or modules.

Those skilled in the art will also appreciate that embodiments herein further include corresponding computer programs.

A computer program comprises instructions which, when executed on at least one processor of computing equipment 200, cause the computing equipment 200 to carry out any of the respective processing described above. A computer program in this regard may comprise one or more code modules corresponding to the means or units described above.

Embodiments further include a carrier containing such a computer program. This carrier may comprise one of an electronic signal, optical signal, radio signal, or computer readable storage medium.

In this regard, embodiments herein also include a computer program product stored on a non-transitory computer readable (storage or recording) medium and comprising instructions that, when executed by a processor of computing equipment 200, cause the computing equipment 200 to perform as described above.

Embodiments further include a computer program product comprising program code portions for performing the steps of any of the embodiments herein when the computer program product is executed by computing equipment 200. This computer program product may be stored on a computer readable recording medium.

In certain embodiments, some or all of the functionality described herein may be provided by processing circuitry executing instructions stored on in memory, which in certain embodiments may be a computer program product in the form of a non-transitory computer-readable storage medium. In alternative embodiments, some or all of the functionality may be provided by the processing circuitry without executing instructions stored on a separate or discrete device-readable storage medium, such as in a hard-wired manner. In any of those particular embodiments, whether executing instructions stored on a non-transitory computer-readable storage medium or not, the processing circuitry can be configured to perform the described functionality. The benefits provided by such functionality are not limited to the processing circuitry alone or to other components of the computing device, but are enjoyed by the computing equipment 200 as a whole.

What is claimed is:

1. A method performed by computer equipment, the method comprising:
receiving a phasor measurement unit (PMU) data stream captured by one or more PMUs in a power distribution system, the PMU data stream being time-synchronized to a global time source;
receiving a sensor data stream captured by a distribution sensor in the power distribution system, the sensor data stream not being time-synchronized to the global time source;
applying dynamic time warping (DTW) processing to the sensor data stream and the PMU data stream to calculate a warping path that minimizes a DTW distance between signal shapes in the sensor data stream and corresponding signal shapes in the PMU data stream; and
performing monitoring, control, and/or event analysis in the power distribution system using the warping path and/or the sensor data stream as warped in time according to the warping path to be time-aligned with the PMU data stream.

2. The method of claim 1, wherein receiving the sensor data stream comprises receiving a time-domain representation of the sensor data stream, and wherein the method further comprises converting the time-domain representation to a phasor-representation of the sensor data stream, wherein applying the DTW processing comprises applying the DTW processing to the phasor-representation of the sensor data stream and the PMU data stream to calculate the warping path that minimizes the DTW distance between the phasor-representation of the sensor data stream and the PMU data stream.

3. The method of claim 1, further comprising correlating event data in the sensor data stream that represents an event in the power distribution system with corresponding event data in the PMU data stream that represents a corresponding event, and wherein applying the DTW processing comprises applying the DTW processing to the event data in the sensor data stream and the corresponding event data in the PMU data stream to calculate a warping path that minimizes a DTW distance between signal shapes represented by the event data in the sensor data stream and corresponding signal shapes represented by the corresponding event data in the PMU data stream.

4. The method of claim 3, wherein the event comprises at least one of: a voltage sag, a voltage swell, a fault inception, a breaker open indication, a breaker close indication, a restoration of voltage, a sustained outage, a temporary outage, or a power quality event.

5. The method of claim 1, wherein applying the dynamic time warping (DTW) processing comprises:
computing, by dynamic programming, a DTW distance matrix of cumulative distances between samples of the sensor data stream and samples of the PMU data stream, wherein a cumulative distance for a pair of sample indices (i, j) is computed as a Euclidean distance between a sensor-data sample at index i and a PMU-data sample at index j plus a minimum of cumulative distances previously computed for index pairs (i−1, j), (i, j−1), and (i−1, j−1); and
determining the warping path based on the DTW distance matrix.

6. The method of claim 1, wherein the method further comprises time-aligning the sensor data stream with the PMU data stream by warping the sensor data stream in time according to the warping path, and wherein the monitoring, control, and/or event analysis is performed using the sensor data stream as warped in time according to the warping path to be time-aligned with the PMU data stream.

7. The method of claim 6, wherein time-aligning the sensor data stream with the PMU data stream comprises aligning the sensor data stream and the PMU data stream on a common timescale referenced to the global time source by warping the sensor data stream in time according to the warping path such that samples of the sensor data stream correspond to samples of the PMU data stream at common time points.

8. The method of claim 1, wherein the warping path permits non-uniform time stretching and compression while maintaining monotonic time order.

9. The method of claim 1, wherein the PMU data stream and the sensor data stream are captured at different time resolutions and/or at different locations.

10. The method of claim 1, wherein performing monitoring, control, and/or event analysis in the power distribution system comprises determining, based on the warping path, a synchronization error of the distribution sensor.

11. The method of claim 1, wherein the sensor data stream comprises an event record captured by the distribution sensor for an event in the power distribution system, and wherein performing monitoring, control, and/or event analysis in the power distribution system comprises calculating, validating, and/or classifying an occurrence, timing, and/or duration of the event using the PMU data stream and the time-aligned sensor data stream.

12. The method of claim 1, wherein the one or more PMUs are installed at a substation, a feeder recloser, a customer site, or a renewable energy interconnection in the power distribution system, and wherein the distribution sensor comprises a power quality meter (PQM) installed at the substation, the customer site, or the renewable energy interconnection, or comprises a smart meter installed at a customer site or the renewable energy interconnection.

13. The method of claim 1, wherein the distribution sensor comprises at least one of: a supervisory control and data acquisition (SCADA) device, a power quality meter (PQM), a relay, a recloser, or a smart meter in an advanced metering infrastructure (AMI) system.

14. The method of claim 1, wherein applying the DTW processing comprises applying the DTW processing to a non-outage part of the PMU data stream and a corresponding non-outage part of the sensor data stream, and wherein the method further comprises, for an outage part of the sensor data stream that includes zero values or missing values indicative of an outage or blackout, time-aligning the sensor data stream with the PMU data stream by aligning an outage start time and an outage end time indicated in the sensor data stream with an outage start time and an outage end time detected in the PMU data stream.

15. A non-transitory computer-readable storage medium on which is stored instructions that, when executed by processing circuitry of computer equipment, causes the computer equipment to:
receive a phasor measurement unit (PMU) data stream captured by one or more PMUs in a power distribution system, the PMU data stream being time-synchronized to a global time source;
receive a sensor data stream captured by a distribution sensor in the power distribution system, the sensor data stream not being time-synchronized to the global time source;
apply a dynamic time warping (DTW) processing to the sensor data stream and the PMU data stream to calculate a warping path that minimizes a DTW distance between signal shapes in the sensor data stream and corresponding signal shapes in the PMU data stream; and
perform monitoring, control, and/or event analysis in the power distribution system using the warping path and/or the sensor data stream as warped in time according to the warping path to be time-aligned with the PMU data stream.

16. Computer equipment comprising processing circuitry configured to:
receive a phasor measurement unit (PMU) data stream captured by one or more PMUs in a power distribution system, the PMU data stream being time-synchronized to a global time source;
receive a sensor data stream captured by a distribution sensor in the power distribution system, the sensor data stream not being time-synchronized to the global time source;
apply a dynamic time warping (DTW) processing to the sensor data stream and the PMU data stream to calculate a warping path that minimizes a DTW distance between signal shapes in the sensor data stream and corresponding signal shapes in the PMU data stream; and
perform monitoring, control, and/or event analysis in the power distribution system using the warping path and/or the sensor data stream as warped in time according to the warping path to be time-aligned with the PMU data stream.
